(19) United States
(12) Patent Application Publication
(10) Pub. No.: US 2003/0210080 A1
(43) Pub. Date: Nov. 13, 2003

(54) Buffer circuit using a transconductance multiplier

(76) Inventor: Xiaoyu Xi, Plano, TX (US)

Correspondence Address: TEXAS INSTRUMENTS INCORPORATED, P O BOX 655474, M/S 3999, DALLAS, TX, 75265

(21) Appl. No.: 10/142,321

(22) Filed: May 9, 2002

(51) Int. Cl. H03B 1/00

(52) U.S. Cl. 327/108

(57) ABSTRACT

The buffer circuit using a transconductance amplifier has a unity-gain feedback configured amplifier which includes: a first transistor M3; a second transistor M4 mirroring a current in the first transistor M3, the second transistor M4 is sized larger than the first transistor M3; a third transistor M1 coupled :o the first transistor; a fourth transistor M2 coupled to the second transistor M1, the fourth transistor M2 is sized larger than the third transistor M1; and a tail current source MS coupled to the third and fourth transistors M1 and M2. The second and fourth transistors M4 and M2 are sized larger than the first and third transistors M3 and M1 to form a transconductance multiplier. This reduces output impedance without increasing bias current.

### FIELD OF THE INVENTION

This invention generally relates to electronic systems and in particular it relates to buffer circuits using transconductance multipliers.

### BACKGROUND OF THE INVENTION

The most commonly used buffers in CMOS integrated circuits are source followers, which are the simplest and potentially the fastest due to the single pole characteristic. However, the source follower also introduces level shifting which in some applications is undesired. When level shifting is a problem, unity-gain feedback configured amplifiers are typically used. But the output impedance of the unity-gain amplifier (buffer) is not as low as the source follower for a fixed bias current and the same transistor size.

The output impedance of the source followers is directly calculated as:

$${r}_{o} \approx \frac{1}{{g}_{m}} = \frac{1}{\sqrt{k \frac{W}{L} {I}_{D}}} \qquad ( 1 )$$

where I_{D} is the bias current of the MOS transistor and

$$\frac{W}{L}$$

is the size of the transistor.

An example five-transistor unity gain amplifier is shown in FIG. 1. The amplifier includes transistors M1-M5, input VIN, output VOUT, source voltage VDD, and bias voltage VBIAS. For the unity-gain amplifier shown in FIG. 1, the output impedance can be easily calculated using the small signal model shown in FIG. 2. The small signal model includes current sources gm1*V1, gm2*V2, gm3*V3, and gm4*V3; resistors Ro1, Ro2, Ro3, Ro4, and Ro5; and voltages V1, V2, V3, Vx, and Vo; and current io. The output impedance calculation for the five-transistor unity gain amplifier is shown below:

gₘ₂(vₒ−vₓ)+gₘ₄v₃+(vₒ−vₓ)gₒ₂+vₒgₒ₄=i ₒ (2)

vₓgₒ₅+gₘ₁vₓ=gₘ₂(vₒ−vₓ)+(v₃−vₓ)gₒ₁+(vₒ−vₓ)gₒ₂ (3)

gₘ₁vₓ−(v₃−vₓ)gₒ₁−v₃gₒ₃=gₘ₃v₃ (4)

Where gₒ₁-gₒ₅ are the transconductances for resistors Ro1-Ro5.

If the amplifier is biased properly, as usual, assume gₒ<<gₘ and the mathematical derivations can be simplified. From equation (4),

$${v}_{3} = \frac{{g}_{m1}}{{g}_{m3}} {v}_{X} ,$$

and from equation (3),

$${v}_{X} = \frac{{g}_{m2}}{{g}_{m1} + {g}_{m2}} {v}_{O} .$$

Then from equation (2), substitute v₃ and vₓ to get the output impedance rₒ as:

$${r}_{O} = \frac{{v}_{O}}{{i}_{O}} = \frac{( {g}_{m1} + {g}_{m2} ) {g}_{m3}}{( {g}_{m3} + {g}_{m4} ) {g}_{m1} {g}_{m2}} \qquad ( 5 )$$

Usually, the amplifier is designed symmetric where transistor M1 and M2 are equal, and transistor M3 and M4 are equal, and their bias currents are the same, thus gₘ₁=gₘ₂ and Gₘ₃=gₘ₄, so equation (5) can be further simplified as:

$${r}_{O} = \frac{1}{{g}_{m1}} = \frac{1}{\sqrt{k \frac{W}{L} {I}_{D1}}} = \frac{1}{\sqrt{k \frac{W}{L} \frac{{I}_{TAIL}}{2}}} \qquad ( 6 )$$

where

$$\frac{W}{L}$$

is the size of the input pair M1 and M2.

Compared to equation (1), the output impedance of the unity-gain amplifier is \sqrt{2} times of that of a source follower with the same bias current and transistor size. To compensate the lost gₘ₁, one has to either double the W or the bias current. But there is a point that increasing W will no longer lift gₘ₁, then to increase the bias current is the only option.

### SUMMARY OF THE INVENTION

A buffer circuit using a transconductance amplifier has a unity-gain feedback configured amplifier which includes: a first transistor; a second transistor mirroring a current in the first transistor, the second transistor is sized larger than the first transistor; a third transistor coupled to the first transistor; a fourth transistor coupled to the second transistor, the fourth transistor is sized larger than the third transistor; and a tail current source coupled to the third and fourth transistors. The second and fourth transistors are sized larger than the first and third transistors to form a transconductance multiplier. This reduces output impedance without increasing bias current.

### BRIEF DESCRIPTION OF THE DRAWINGS

In the drawings

FIG. 1 is a schematic circuit diagram of a five-transistor unity gain amplifier;

FIG. 2 is a schematic circuit diagram o: a small signal model of the circuit of FIG. 1;

FIG. 3 is a detailed schematic circuit diagram of an example implementation of a preferred embodiment buffer circuit with a transconductance multiplier.

### DETAILED DESCRIPTION OF PREFERRED EMBODIMENTS

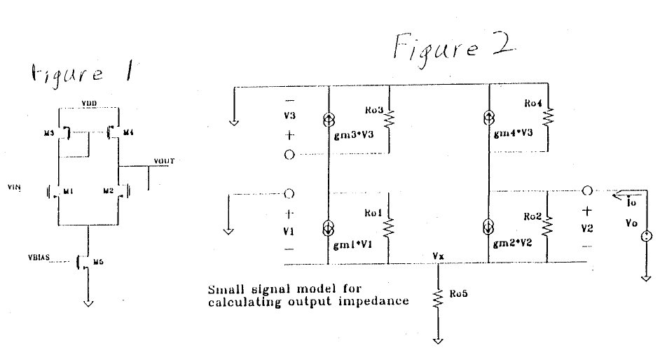

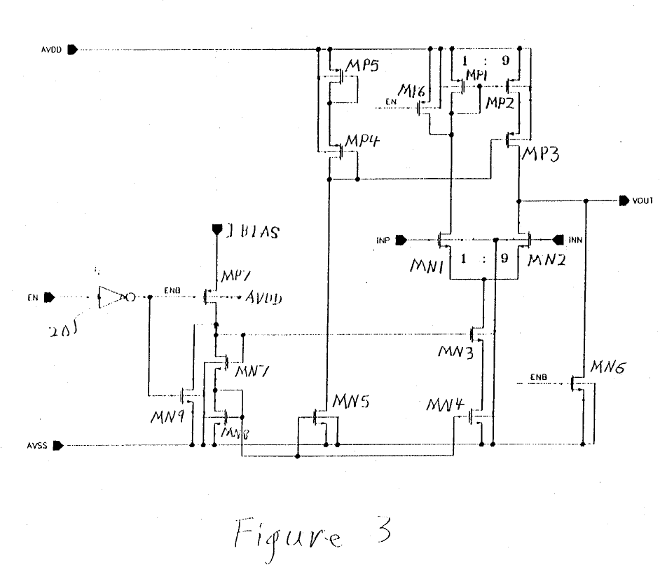

In the preferred embodiment configuration, transistors M2 and M4, of FIG. 1, are sized larger than transistors M1 and M3. This reduces output impedance without increasing bias current or the transistor size by using a transconductance (Gm) multiplier. Looking at equation (5), assume gₘ₄=x·gₘ₃ and gₘ₂=x·gₘ₁, then the output impedance is

$${r}_{O} = \frac{{v}_{O}}{{i}_{O}} = \frac{( 1 + x ) {g}_{m1} {g}_{m3}}{( 1 + x ) {g}_{m3} {g}_{m1} \cdot x {g}_{m1}} = \frac{1}{x \cdot {g}_{m1}} \qquad ( 7 )$$

which is x times smaller than in equation (6). In circuit design, the ratio x is simply obtained by sizing transistor M2 to x times transistor M1, and transistor M4 to x times transistor M3. Keep in mind that the above statement is only true transistor M1 size remains the same, which implies the transistor M2 and the total area will be roughly x times larger than the conventional unity-gain amplifier.

To make an accurate comparison with the conventional amplifier (x=1), assume the bias current I_{TAIL} is fixed and e total transistor area remains the same. As shown in equation (6), for a conventional unity-gain amplifier, the output impedance rₒ is

$$\frac{1}{{g}_{m1}} = \frac{1}{\sqrt{k \frac{W}{L} \frac{{I}_{TAIL}}{2}}} .$$

While for a Gm multiplied buffer, the output impedance rₒ is

$$\frac{1}{x \cdot {g}_{m1}} = \frac{1}{x \sqrt{k ( \frac{W}{L} \cdot \frac{2}{1 + x} ) \frac{{I}_{TAIL}}{1 + x}}} = \frac{1}{\frac{x}{1 + x} \sqrt{k \frac{W}{L} ( 2 \cdot {I}_{TAIL} )}} \approx \frac{1}{2 \sqrt{k \frac{W}{L} \frac{{I}_{TAIL}}{2}}} ,$$

for the ratio x much greater than 1, and rₒ about 50% smaller than that of a conventional unity-gain amplifier. Even if x is not much greater than 1, rₒ is still

$$\frac{1 + x}{2 \cdot x}$$

of that of the conventional buffer. As a benefit, the bandwidth of the exact same circuit will be increased up to twice as wide.

The circuit of FIG. 3 is a buffer circuit example using the preferred embodiment Gm multiplier with x=9. The circuit of FIG. 3 includes NMOS transistors MN1-MN9; PMOS transistors MP1-MP7; inverter 20; bias current IBIAS; source voltages AVDD and AVSS; enable signals EN and ENB; input signals INP and INM; and output VOUT. In comparison with a conventional buffer with balanced input pair (x=1), the bandwidth of the preferred embodiment buffer is almost doubled. The internal parasitic pole also comes in at lower frequency due to smaller transconductance gₘ₃.

While this invention has been described with reference to an illustrative embodiment, this description is not intended to be construed in a limiting sense. Various modifications and combinations of the illustrative embodiment, as well as other embodiments of the invention, will be apparent to persons skilled in the art upon reference to the description. It is therefore intended that the appended claims encompass any such modifications or embodiments.

What is claimed is:

1. A circuit comprising:
a first transistor;
a second transistor mirroring a current in the first transistor, the second transistor is at least a few times larger than the first transistor;
a third transistor coupled to the first transistor;
a fourth transistor coupled to the second transistor, the fourth transistor is at least a few times larger than the third transistor; and
a tail current source coupled to the third and fourth transistors.

2. The circuit of claim 1 wherein the first, second, third, and fourth transistors are MOS transistors.

3. The circuit of claim 1 wherein the first and second transistors are PMOS transistors.

4. The circuit of claim 1 wherein the third and fourth transistors are NMOS transistors.

5. The circuit of claim 1 further comprising a fifth transistor coupled between the second and fourth transistor.

6. The circuit of claim 5 wherein the fifth transistor is a PMOS transistor.

7. The circuit of claim 1 wherein a gate of the third transistor is coupled to a first input node and a gate of the fourth transistor is coupled to a second input node.

8. The circuit of claim 1 wherein an output node is coupled between the second transistor and the fourth transistor.

9. A buffer circuit comprising:
a first MOS transistor having a gate coupled to a first input node;
a second MOS transistor coupled to the first MOS transistor;
a third MOS transistor having a gate coupled to a gate of the second MOS transistor, the third MOS transistor is at least a few times larger than the second MOS transistor;
a fourth MOS transistor coupled to the third MOS transistor and having a gate coupled to a second input node, the fourth MOS transistor is at least a few times larger than the first MOS transistor; and
a tail current source coupled to the first and fourth transistors.

10. The circuit of claim 9 wherein the second and third MOS transistors are PMOS transistors.

11. The circuit of claim 9 wherein the first and fourth MOS transistors are NMOS transistors.

12. The circuit of claim 9 further comprising a fifth MOS transistor coupled between the second and fourth transistor.

13. The circuit of claim 12 wherein the fifth MOS transistor is a PMOS transistor.

14. The circuit of claim 9 wherein an output node is coupled between the third MOS transistor and the fourth MOS transistor.

15. The circuit of claim 9 wherein the gate of the second MOS transistor is coupled to a drain of the second MOS transistor.
